(19) United States
(12) Patent Application Publication
(10) Pub. No.: US 2014/0147955 A1
(43) Pub. Date: May 29, 2014

(54) METHOD OF ENCAPSULATING A MICRO-ELECTROMECHANICAL (MEMS) DEVICE

(71) Applicants: Jae-Wung Lee, Singapore (SG); Jaibir Sharma, Singapore (SG); Navab Singh, Singapore (SG); Julius Ming Ling Tsai, Singapore (SG)

(72) Inventors: Jae-Wung Lee, Singapore (SG); Jaibir Sharma, Singapore (SG); Navab Singh, Singapore (SG); Julius Ming Ling Tsai, Singapore (SG)

(73) Assignee: Agency for Science, Technology and Research, Singapore (SG)

(21) Appl. No.: 14/093,348

(22) Filed: Nov. 29, 2013

(30) Foreign Application Priority Data
Nov. 29, 2012 (SG) 201208835-7

(51) Int. Cl. B81C 1/00

(52) U.S. Cl. CPC B81C 1/00333
USPC 438/51

(57) ABSTRACT

A method for encapsulating a micro-electromechanical (MEMS) device, the method comprising: providing a sacrificial layer arrangement over the MEMS device; providing a first encapsulation layer over the sacrificial layer arrangement, the first encapsulation layer defining at least one aperture; providing a second encapsulation layer over the at least one aperture, the second encapsulation layer being provided to allow removal of the sacrificial layer arrangement around the second encapsulation layer; and removing the sacrificial layer arrangement through the at least one aperture to allow the second encapsulation layer to cover the at least one aperture thereby encapsulating the MEMS device.

### PRIORITY APPLICATION(S)

The present application claims the benefit of priority under 35 U.S.C. §119 to Singapore Patent Application No. 201208835-7, filed Nov. 29, 2012, which is incorporated herein by reference in its entirety.

### FIELD OF INVENTION

The invention relates generally to a method of encapsulating a micro-electromechanical (MEMS) device.

### BACKGROUND

Micro-electromechanical system (MEMS) devices are very small devices and are used in cutting edge applications such as sensors, optics and radio-frequency (RF) devices. They generally range in size from 20 micrometres (20 millionths of a metre) to a millimetre (i.e. 0.02 to 1.0 mm). Each MEMS device usually consists of several components that interact with the surroundings such as micro sensors.

MEMS devices are generally sensitive to their environmental conditions. Moreover, MEMS devices require a certain degree of space to effect translational movement. As such, MEMS devices should be cleared of any particulate matter that may inhibit movement of the MEMS devices.

Encapsulation is an attractive technique to protect the MEMS device because an encapsulation effectively protects the MEMS device during dicing. Furthermore, an encapsulation provides proper ambient environment for its optimum operation. It is also cheaper to encapsulate a MEMS device than to perform wafer bonding.

For example, one conventional encapsulation technique provides a single-layer encapsulation. However, such a single-layer encapsulation may be deformed or broken when an external pressure is applied.

Other conventional techniques may provide a two layer encapsulation. However, some of these techniques may result in a longer time to release the sacrificial layer. In other instances, the conventional techniques may result in mass loading of the MEMS device. This means that unwanted material may fall through an etch channel and cause damage to the MEMS device by the conventional encapsulation techniques.

Thus, it would be beneficial to encapsulate the MEMS device without all these problems. However, with the existing techniques, it is difficult to provide an effective encapsulation method.

A need therefore exists to provide a method which can be used to encapsulate the MEMS device.

### SUMMARY

According to a first aspect, there is provided a method for encapsulating a micro-electromechanical (MEMS) device, the method comprising: providing a sacrificial layer arrangement over the MEMS device; providing a first encapsulation layer over the sacrificial layer arrangement, the first encapsulation layer defining at least one aperture; providing a second encapsulation layer over the at least one aperture, the second encapsulation layer being provided to allow removal of the sacrificial layer arrangement around the second encapsulation layer; and removing the sacrificial layer arrangement through the at least one aperture to allow the second encapsulation layer to cover the at least one aperture thereby encapsulating the MEMS device.

In an embodiment, the method further comprising a step of moving the second encapsulation layer away from the sacrificial layer arrangement to expose the at least one aperture after the step of providing the second encapsulation layer over the sacrificial layer arrangement.

In an embodiment, the method further comprising the step of moving the second encapsulation layer towards the first encapsulation layer so as to cover the exposed at least one aperture thereby encapsulating the MEMS device.

In an embodiment, the steps of moving the second encapsulation layer away from the sacrificial layer arrangement and removing the sacrificial layer arrangement through the exposed aperture are performed at the same time.

In an embodiment, the sacrificial layer arrangement comprises a first sacrificial layer provided. over the MEMS device, the method further comprises providing a second sacrificial layer over the at least one aperture and wherein the removing step comprises removing the first sacrificial layer and the second sacrificial layer.

In an embodiment, the second sacrificial layer is removed first followed by removing the first sacrificial layer.

In an embodiment, the first sacrificial layer is removed through the exposed at least one aperture.

In an embodiment, the second encapsulation layer is moved by an external force.

In an embodiment, the external force comprises magnetic force, piezoelectric force, gravitational force, thermal force, electro-thermal force and electromagnetic force.

In an embodiment, the second encapsulation layer moves towards the first encapsulation layer when the external force is removed.

In an embodiment, the sacrificial layer arrangement further comprises a third sacrificial layer, the third sacrificial layer being provided beside the second sacrificial layer.

In an embodiment, the third sacrificial layer is made of the same material as the first sacrificial layer.

In an embodiment, the first sacrificial layer and the third sacrificial layer are removed first followed by removing the second sacrificial layer.

In an embodiment, the method further comprises patterning the second encapsulation layer.

In an embodiment, patterning the second encapsulation layer comprises forming a plurality of etch holes, the plurality of etch holes being configured to align with a portion of the first encapsulation. layer.

In an embodiment, a dissolving agent is provided to the sacrificial layer arrangement through the plurality of etch holes.

In an embodiment, the first sacrificial layer comprises silicon oxide.

In an embodiment, the second sacrificial layer comprises amorphous silicon, poly silicon and single crystalline silicon.

In an embodiment, the second encapsulation layer comprises a biasing element, the biasing element being coupled to the first encapsulation layer so as to allow the second encapsulation layer moves away from the sacrificial layer arrangement.

In an embodiment, encapsulating the MEMS device comprises enclosing the MEMS device under vacuum.

In an embodiment, the second encapsulation layer comprises nickel, iron, cobalt or any combination including nickel, iron and/or cobalt.

In an embodiment, the method further comprises forming a sealing layer to enclose the first and second encapsulation layers.

In an embodiment, the aperture is arranged in a substantially central location on an upper surface of the sacrificial layer arrangement.

In an embodiment, the first and second sacrificial layers are made of different materials.

In an embodiment, the first and second encapsulation layers are made of different materials.

In an embodiment, the first encapsulation layer and the second encapsulation layer are configured to release stress during the step of forming a sealing layer.

In an embodiment, the first encapsulation layer and the second encapsulation layer are configured to release stress after the step of forming a sealing layer.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows a cross-sectional view of a MEMS device being encapsulated;

FIGS. 2(a)-2(f) illustrate a method of encapsulating the MEMS device in a cross-sectional view in accordance with a first embodiment;

FIGS. 3(a)-(h) illustrate a method of encapsulating the MEMS device in a cross-sectional view in accordance with a second embodiment;

FIGS. 4(a)-(h) illustrate the method of encapsulating the MEMS device in a plan view in accordance with the second embodiment;

FIGS. 5(a)-(b) illustrate the method of encapsulating the MEMS device in a cross-sectional view in accordance with the second embodiment;

FIGS. 6(a)-(b) illustrate the method of encapsulating the MEMS device in a plan view in accordance with the second embodiment;

FIGS. 7(a)-(h) illustrate a method of encapsulating the MEMS device in a cross-sectional view in accordance with a third embodiment;

FIGS. 8(a)-(h) illustrate the method of encapsulating the MEMS device in a plan view in accordance with the third embodiment;

FIGS. 9(a)-(f) illustrate the method of encapsulating the MEMS device in a cross-sectional view in accordance with the third embodiment;

FIGS. 10(a)-(c) show how the second encapsulation layer of FIG. 7 may be moved by using magnetic or electrostatic force;

FIGS. 11(a)-(c) show how the second encapsulation layer of FIG. 7 may be moved by using thermal force;

FIGS. 12(a)-(c) show how the second encapsulation layer of FIG. 7 may be moved by using gravitational force; and

FIGS. 13(a)-(c) show how the second encapsulation layer of FIG. 7 may be moved by using piezoelectric force.

### DETAILED DESCRIPTION

Various embodiments relate to a method for encapsulating a micro-electromechanical system (MEMS) device.

Referring to FIG. 1, an encapsulation layer arrangement 106, 108 for a MEMS device 104 is shown. The MEMS device 104 is arranged on a substrate 102. The encapsulation layer arrangement includes a first encapsulation layer 106 and a second encapsulation layer 108. The encapsulation layer arrangement is arranged to be spaced apart from the MEMS device 104 and encapsulates the MEMS device 104 in vacuum. The first encapsulation layer 106 is provided over the MEMS device 104 and defines at least one aperture. The at least one aperture may be defined on an upper surface of the first encapsulation layer 106. The at least one aperture may be provided in a substantially central portion on the upper surface of the first encapsulation layer 106.

The second encapsulation layer 108 is adapted to provide over the at least one aperture on the first encapsulation layer 106, so as to form an encapsulation layer arrangement for the MEMS device 104. The second encapsulation layer 108 includes an etch hole 109. The second encapsulation layer 108 may also include a plurality of etch holes 109. The etch hole or the plurality of etch holes 109 are adapted to align with a portion of the first encapsulation layer 106. Accordingly, the first encapsulation layer 106 and the second encapsulation layer 108 form a discontinuous encapsulation layer arrangement around the MEMS device.

It is to be understood that the MEMS device and the encapsulation layer arrangement may be manufactured by the same or separate entities. In any case, the MEMS device will be subject to a manufacturing process during which the encapsulation layers are fabricated to encapsulate the MEMS device.

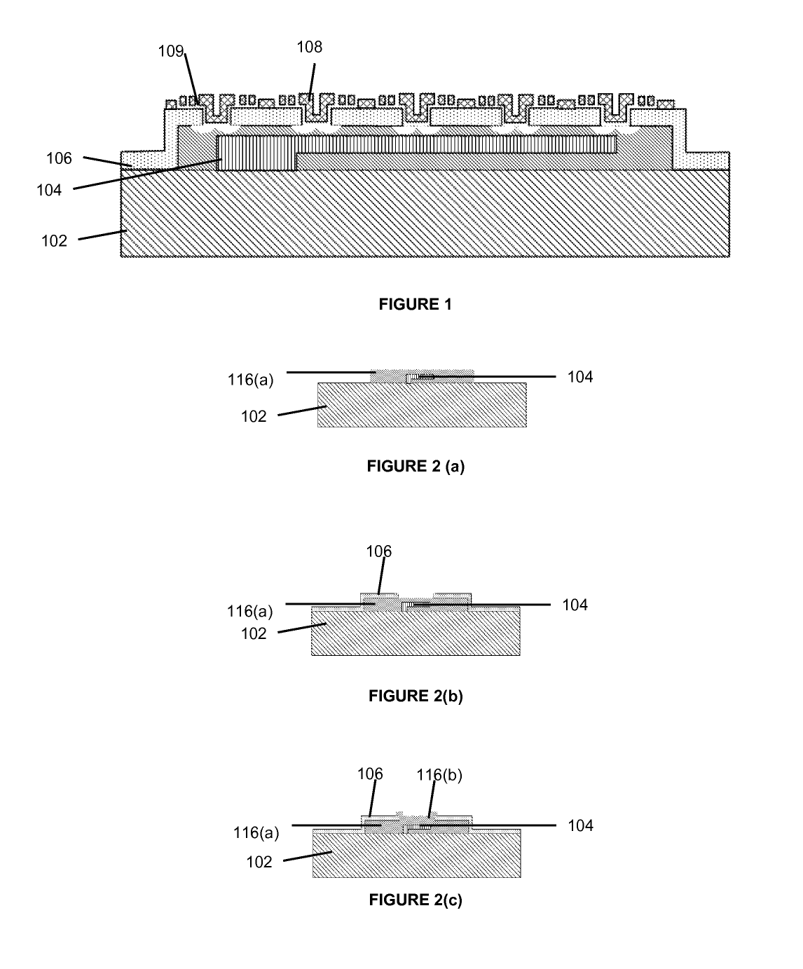

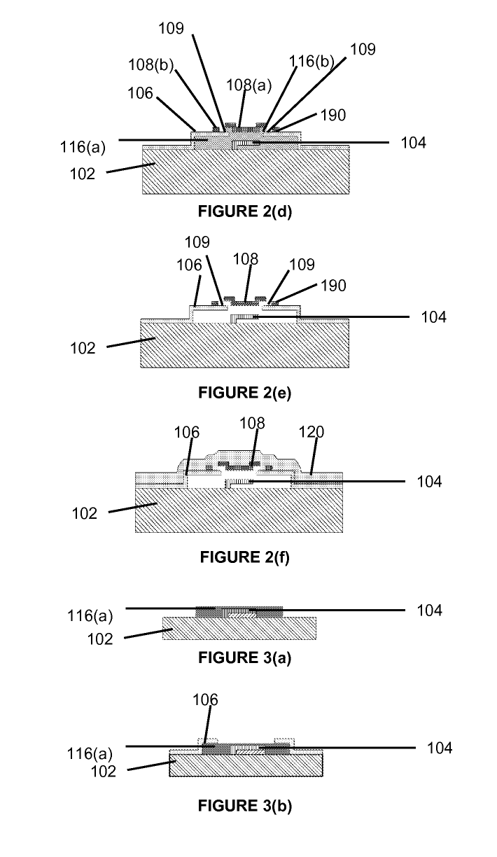

FIGS. 2(a)-(f) illustrate a method for encapsulating the MEMS device, in accordance with the first embodiment. This method aims to provide an effective way to encapsulate the MEMS device using two encapsulation layers and two sacrificial layers. The first encapsulation layer defines one aperture in accordance with the method illustrated in FIGS. 2(a)-(h).

Referring to FIG. 2(a), the MEMS device 104 is arranged on the substrate 102. The substrate 102 may be any suitable substrate such as a silicon substrate and a silicon-on-insulator (SOI) substrate. A sacrificial layer arrangement 116(a) (or “a first sacrificial layer”) is provided on the MEMS device. In the embodiment, the first sacrificial layer 116(a) is provided over the MEMS device 104. This is done by depositing the first sacrificial layer 116(a) to fill the space around the MEMS device 104. An example of the first sacrificial layer 116(a) is silicon oxide, SiO₂.

Referring to FIG. 2(b), a first encapsulation layer 106 is provided over the first sacrificial layer 116(a). The first encapsulation layer 106 defines at least one aperture. The aperture is arranged on a substantially central location on an upper surface of the first encapsulation layer 106. The first encapsulation layer 106 is deposited and patterned using techniques such as physical vapour deposition (PVD) or chemical vapour deposition (CVD). The first encapsulation layer 106 is also patterned using plasma etching process techniques.

Referring to FIG. 2(c), a sacrificial layer arrangement 116(b) (or “a second sacrificial layer”) is arranged over the first sacrificial layer 116(a). The second sacrificial layer 116(b) includes a portion that covers the aperture when the second sacrificial layer arrangement 116(b) is provided over the first sacrificial layer 116(a). Further, the second sacrificial layer 116(b) may comprise portions that extend from the covering portion. These extending portions are provided over the first encapsulation layer 106.

Referring to FIG. 2(d), the second encapsulation layer 108 is provided over the second sacrificial layer 116(b) and the at least one aperture. In the embodiment, a corresponding portion 108(a) of the second encapsulation layer 108 is configured to be lower than the other parts of the second encapsulation layer 108 and completely covers the at least one aperture.

The second encapsulation layer 108 includes separate portions 108(b) extending from the covering portion 108(a). These separate portions are patterned to provide at least one etch hole 109. The etch hole 109 is configured to align with a portion of the first encapsulation layer 106. In the embodiment, the etch hole is arranged over a portion of the first encapsulation layer 106 when the second encapsulation layer 108 is arranged over the first encapsulation layer 106. For example, the first encapsulation layer 106 is overlaid with the second encapsulation layer 108.

Referring to FIG. 2(e), the second sacrificial layer 116(b) is removed while retaining the second encapsulation layer 108 away from the first sacrificial layer 116(a) and the first encapsulation layer 106. In other words, the second encapsulation layer 108 is maintained at a spaced apart distance away from the first sacrificial layer 116(a) and the first encapsulation layer 106. The second encapsulation layer 108 comprises a biasing element 190 that is coupled to the first encapsulation layer 106 at one end so as to allow the second encapsulation layer to move away from the sacrificial layer arrangement. In the embodiment, the biasing element 190 is a serpentine spring which is configured to make the second encapsulation layer 108 to move away and towards the first sacrificial layer 116(a) and the first encapsulation layer 106.

Referring to FIG. 2(f), a sealing layer 120 is provided over the first and second encapsulation layers 106 and 108. The sealing layer 120 is provided to fill the spaces around the first and second encapsulation layers 106 and 108. In this manner, the sealing layer 120 hermetically seals the first and second encapsulation layers 106 and 108. The first encapsulation layer 106 and the second encapsulation layer 108 are configured to release stress of the encapsulation during or after providing the sealing layer 120.

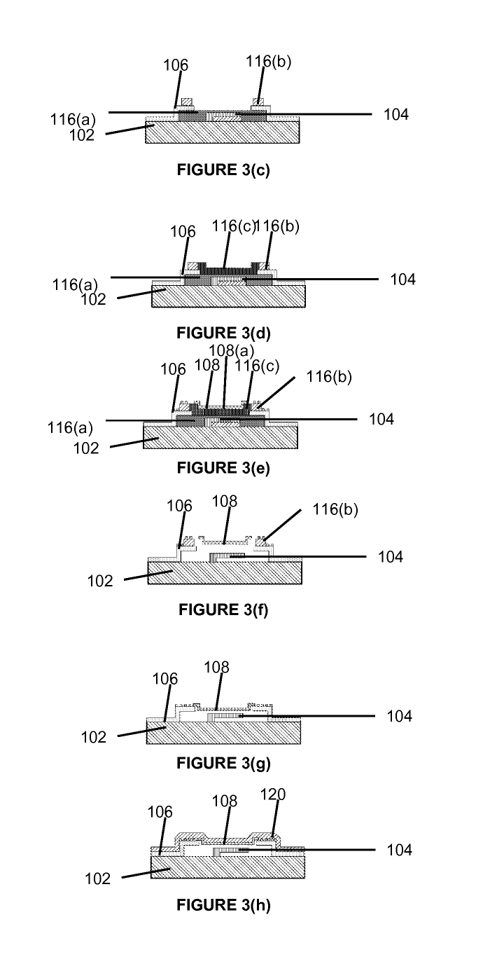

FIGS. 3(a)-(h) illustrate a method for encapsulating the MEMS device in accordance with the second embodiment. This method aims to provide an effective way to encapsulate the MEMS device using two encapsulation layers and three sacrificial layers.

FIGS. 3(a)-(b) are analogous to FIGS. 2(a)-(b). Accordingly, the MEMS device 104 is arranged on the substrate 102 and a sacrificial layer arrangement 116(a) (or “a first sacrificial layer”) is provided on the MEMS device 104.

Referring to FIG. 3(c), a sacrificial layer arrangement 116(b) (or “a second sacrificial layer”) is provided on the first encapsulation layer 106. In the embodiment, the second sacrificial layer 116(b) is not provided on the first sacrificial layer 116(a).

Referring to FIG. 3(d), a sacrificial layer arrangement 116(c) (or “a third sacrificial layer”) is provided over the first sacrificial layer 116(a). The third sacrificial layer 116(c) is also provided beside the second sacrificial layer. The third sacrificial layer 116(c) is also configured to cover the aperture. In the embodiment, the third sacrificial layer 116(c) is made of the same material as the first sacrificial layer 116(a).

Referring to FIG. 3(e), a second encapsulation layer 108 is provided over the third sacrificial layer 116(c) and the at least one aperture.

Referring to FIG. 3(f), the second sacrificial layer 116(b) remains on the first encapsulation layer 106. In the embodiment, the second sacrificial layer 116(b) is configured to retain the second encapsulation layer 108 to be spaced apart from the first encapsulation layer 106. The second encapsulation layer 108 has a low spring design which allows it to remain on the second sacrificial layer 116(b). This helps to retain the second encapsulation layer 108 to be spaced apart from the first encapsulation layer 106 during a removal of the first sacrificial layer 116(a) and the third sacrificial layer 116(c).

Referring to FIG. 3(g), the second sacrificial layer 116(b) is removed. Upon a removal of the second sacrificial layer 116(b), the second encapsulation layer 108 moves towards the first encapsulation layer 106 and covers the at least one aperture, since the second encapsulation layer 108 has a low spring constant. This results in a discontinuous two layer encapsulation.

FIG. 3(h) is analogous to FIG. 2(f). Accordingly, a sealing layer 120 is provided over the first and second encapsulation layer 106 and 108, thereby hermetically seals the two encapsulation layers.

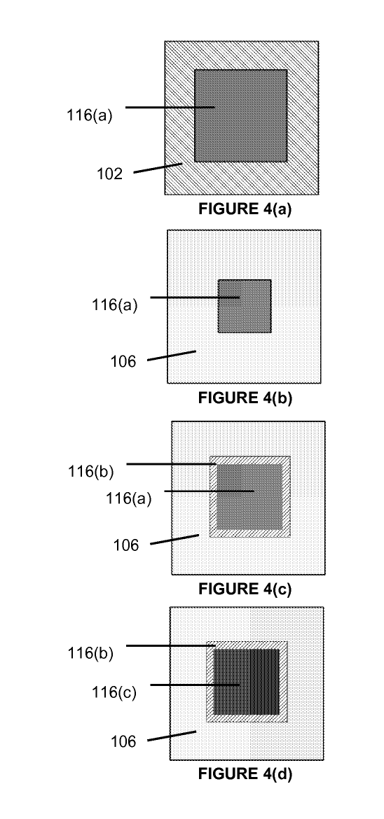

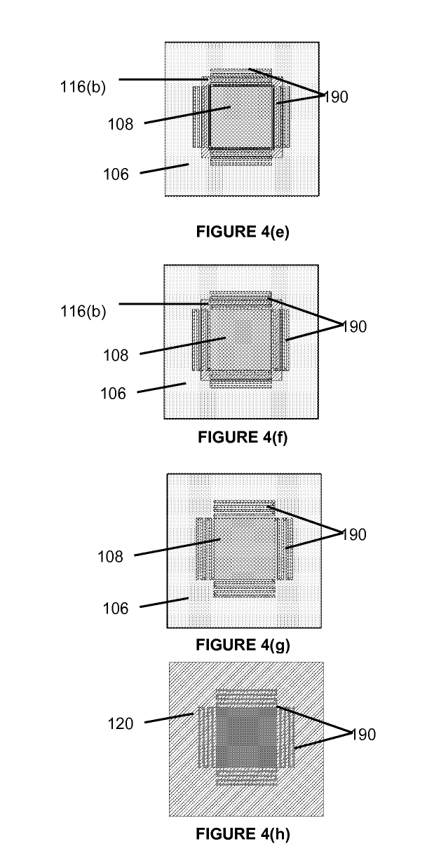

FIGS. 4(a)-(h) illustrate the plan view of the method illustrated in FIGS. 3(a)-(h). Referring to FIGS. 3(a)-(h), the second encapsulation layer 108 is provided in a meander structure 190 through which the first sacrificial layer 116(a), the second sacrificial layer 116(b) or the third sacrificial layer 116(c) are removed. The release time may be effectively reduced by redesigning the meander structure 190. For example, the meander structure 190 may be redesigned to define bigger gaps. Each of these gaps allows the introduction of a dissolving agent which may be used to remove any of the sacrificial layers.

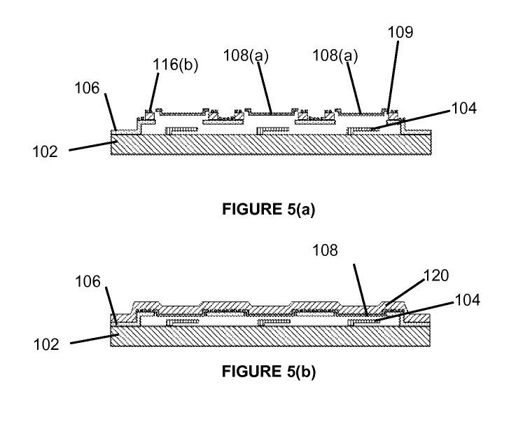

FIGS. 5(a)-(b) illustrate the method of encapsulating the MEMS device in a cross-sectional view in accordance with the second embodiment. The method illustrated in FIGS. 5(a)-(b) uses a plurality of apertures to encapsulate the MEMS device.

FIG. 5(a) is analogous to FIG. 3(f). A portion of the second sacrificial layer 116(b) remains on the first encapsulation layer 106 and is arranged around the aperture. In the embodiment, the second sacrificial layer 116(b) is configured to retain the second encapsulation layer 108 to be spaced apart from the MEMS device 104.

The second encapsulation layer 108 is configured to include a plurality of covering portions 108(a) and etch holes 109. Each of the plurality of covering portions 108(a) is configured to cover one of the plurality of apertures of the first encapsulation layer 106.

In the embodiment, the second sacrificial layer 116(b) is made of a different material from the first sacrificial layer 116(a) and the third sacrificial layer 116(c). As such, the first sacrificial layer 116(a) and the third sacrificial layer 116(c) are removed first before the second sacrificial layer 116(b) is removed.

Referring to FIG. 5(b), a sealing layer 120 is provided over the first encapsulation layer 106 and the second encapsulation layer 108, thereby encapsulating the MEMS device 104.

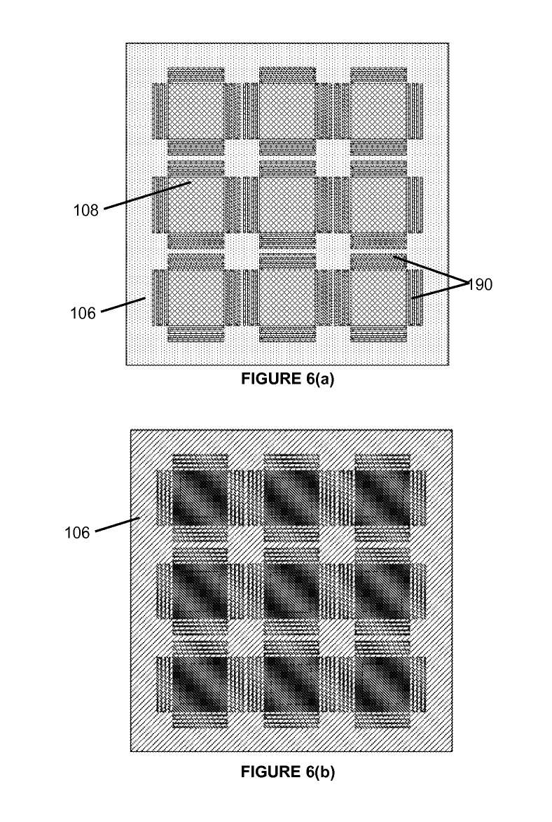

FIGS. 6(a)-(b) illustrate the method of encapsulating the MEMS device in a plan view in accordance with the second embodiment.

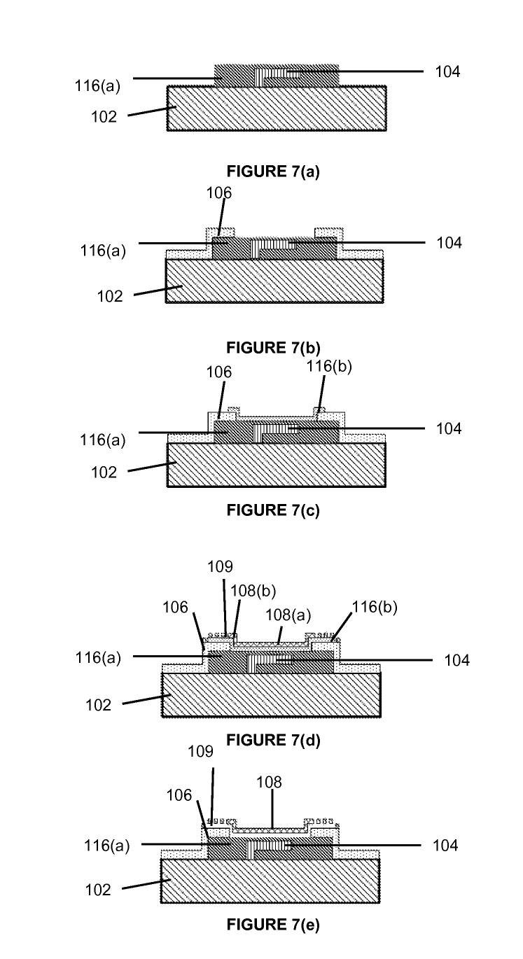

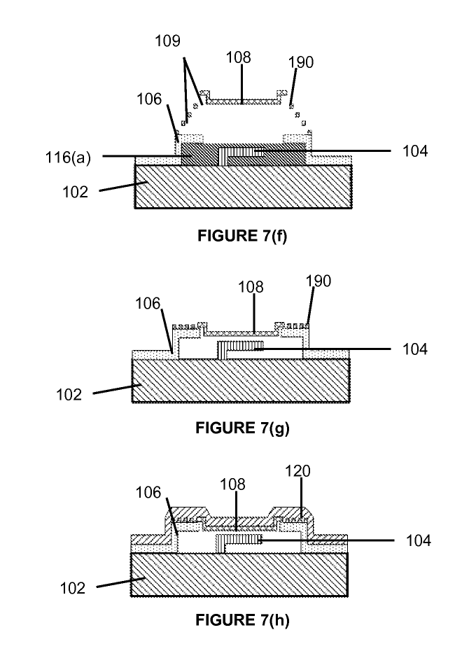

FIGS. 7(a)-(h) illustrate a method of encapsulating the MEMS device in a cross-sectional view in accordance with a third embodiment. FIGS. 7(a)-(e) are analogous to FIGS. 2(a)-(e).

In this embodiment, the first sacrificial layer 116(a) and the second sacrificial layer 116(b) are made of the same material. An example of a material for the sacrificial layer arrangements 116(a) and 116(b) is silicon oxide, SiO₂. As such, the sacrificial layer arrangements 116(a) and 116(6) have similar etching characteristics. In other words, the sacrificial layer arrangements 116(a) and 116(b) etch away when exposed to the same etchant during an etching process.

In another embodiment, the second sacrificial layer 116(b) is made of a different material than the material of the first sacrificial layer 116(a). The material of the second sacrificial layer 116(b) may be less resistant to a dissolving agent than the first sacrificial layer 116(a). This will result in the removal of the second sacrificial layer 116(b) before the first sacrificial layer 116(a). An example is that the first sacrificial layer 116(a) is made of silicon oxide and the second sacrificial layer 116(b) is made of silicon, amorphous silicon, poly silicon or single crystalline silicon.

Referring to FIG. 7(f), the second encapsulation layer 108 is lifted up. In other words, the second encapsulation layer 108 is moved away from the first sacrificial layer 116(a). This means that the covering portion 108(a) of the second encapsulation layer 108 is moved away from the at least one aperture. This effect in turn causes the at least one aperture defined by the first encapsulation layer 106 to be exposed. In the embodiment, the second encapsulation layer 108 is moved away in response to an application of an external force. Examples of the external force will be described in more details below.

The second encapsulation layer 108 includes a meander structure 190. FIG. 7(f) shows that the meander structure 190 is moved away as the second encapsulation layer 108 moves away, thereby defining etch holes 109 in between the meander structure 190. In the embodiment, each of these etch holes 109 allows the introduction of a dissolving agent into the first sacrificial layer 116(a). The dissolving agent gets into contact with the first sacrificial layer 116(a) by entering through at least one etch hole 109 and the at least one aperture. The introduction of a dissolving agent in turns etches away or removes the first sacrificial layer 116(a).

In the embodiment, removal of the first sacrificial layer 116(a) is the process that creates vacuum around the MEMS device 104. The first sacrificial layer 116(a) is etched away or removed in portions until the entire first sacrificial layer 116(a) is etched away or removed. The removal of the first sacrificial layer 116(a) may be performed at the same time as moving the second encapsulation layer 108 away by the external force. It is also possible for the removal of the first sacrificial layer 116(a) to be performed after the second encapsulation layer 108 is moved away by the external force.

In any case, the first sacrificial layer 116(a) will be subject to a removal process during which the first sacrificial layer 116(a) is removed to surround the MEMS device 104 in vacuum. It is to be understood that the removal of the second sacrificial layer 116(b) as illustrated in FIG. 7(e) and the first sacrificial layer 116(a) as illustrated in FIG. 7(f) may be performed using the same or different techniques.

Referring to FIG. 7(g), the second encapsulation layer 108 moves towards the first encapsulation layer 106 so as to cover the exposed at least one aperture. Consequently, the first encapsulation layer 106 is overlaid with the second encapsulation layer 108. This in turn encapsulates the MEMS device 104. In the embodiment, the MEMS device 104 is encapsulated in vacuum. Advantageously, this provides the MEMS device 104 a certain degree of translational freedom to perform its function and is protected from contamination or other harsh environment.

In the embodiment, when the second encapsulation layer 108 is moved towards the first encapsulation layer 106, the meander structure 190 align with portions of the first encapsulation layer 106. This in turn provides a more secure arrangement of the first and second encapsulation layer.

Furthermore, since the first encapsulation layer 106 and second encapsulation layer 108 are maintained at a spaced apart distance from the MEMS device 104, they protect the structure MEMS device during encapsulation.

Referring to FIG. 7(h), a sealing layer 120 is provided over the first and second encapsulation layers. The sealing layer 120 hermetically seals the structure.

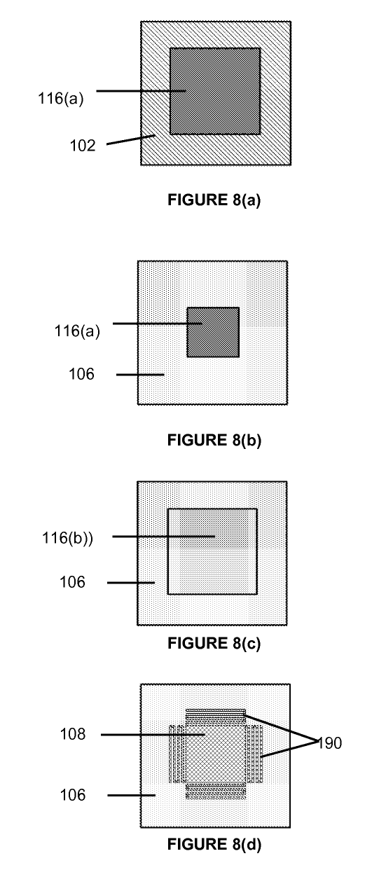

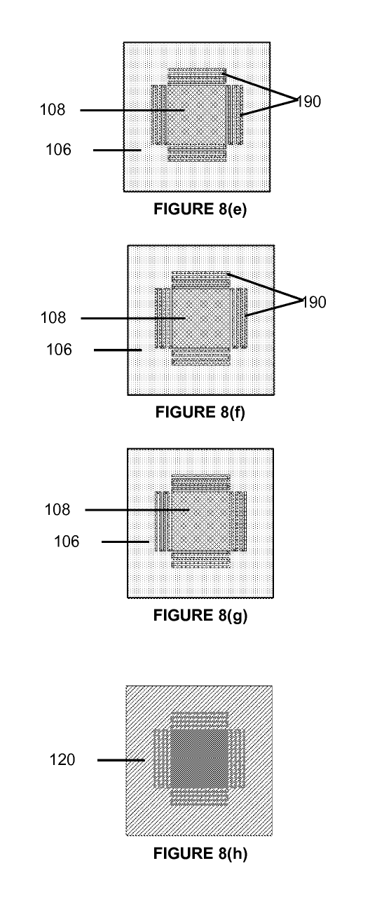

FIGS. 8(a)-(h) illustrate the plan view of the method illustrated in FIGS. 7(a)-(h). Referring to FIGS. 8(a)-(h), the meander structure 190 of the second encapsulation layer 108 provides the etch holes through which the sacrificial layer arrangement may be removed. The release time may be effectively reduced by re-designing the meander structure 190. For example, the meander structure 190 may be re-designed to define bigger etch holes. Each of these etch holes allows the introduction of a dissolving agent into the first sacrificial layer 116(a), as shown in FIG. 7(f).

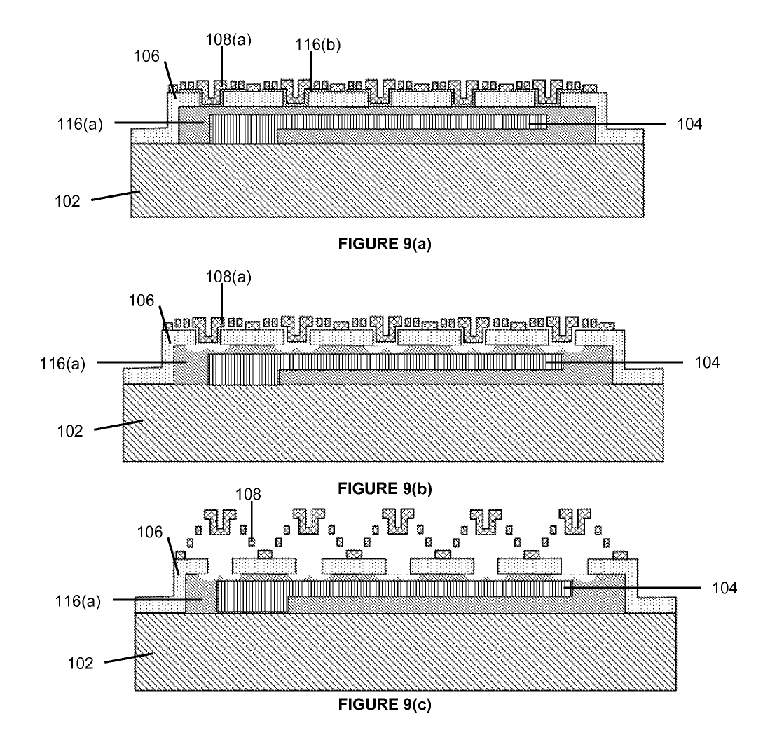

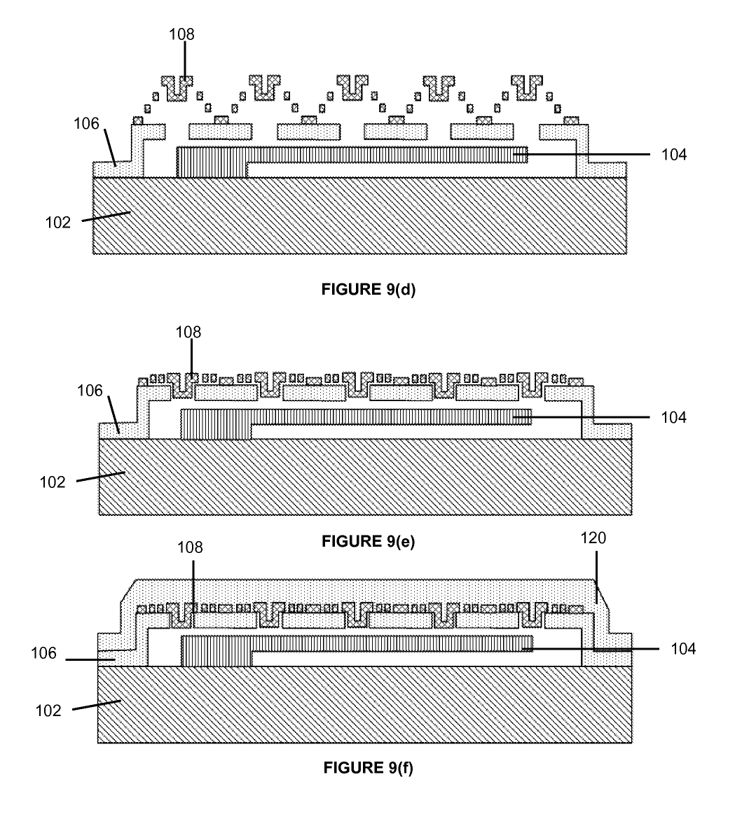

FIGS. 9(a)-(f) illustrate the cross section view of using a plurality of apertures to encapsulate the MEMS device in accordance with the third embodiment. Referring to FIG. 9(a), a plurality of apertures are defined by the first encapsulation layer 106. The plurality of apertures are arranged above the MEMS device. The second encapsulation layer 108 is configured to include a plurality of covering portions 108(a). Each of the plurality of covering portions is configured to cover one of the plurality of apertures of the first encapsulation layer 106. In the embodiment, the first encapsulation layer 106 and the second encapsulation layer 108 are made of the same material.

In the embodiment, the first sacrificial layer 116(a) and the second sacrificial layer 116(b) are made of the same material. Referring to FIG. 9(b), the sacrificial layer arrangement 116(b) is removed first while the second encapsulation layer 108 is retained over the first encapsulation layer 106.

Referring to FIG. 9(c), the second encapsulation layer 108 is moved away from the first encapsulation layer 106. The second encapsulation layer 108 may be moved away after the second sacrificial layer 116(b) is removed. Alternatively, the second encapsulation layer 108 may be moved away at the same time that the second sacrificial layer 116(b) is removed. This exposes the plurality of apertures of the first encapsulation layer 106. Each of the plurality of apertures is configured to etch or remove the first sacrificial layer 116(a). In the embodiment, a dissolving agent may be introduced.

Referring to FIG. 9(d), the first sacrificial layer 116(a) is etched or removed in portions until the entire the first sacrificial layer 116(a) is removed.

Referring to FIG. 9(e), the second encapsulation layer 108 is provided over the first encapsulation layer 106. This effectively covers all the apertures of the first encapsulation layer, thereby encapsulating the MEMS device 104.

Referring to FIG. 9(f), a sealing layer 120 is provided over the first encapsulation layer 106 and the second encapsulation layer 108. The sealing layer 120 hermetically seals the structure.

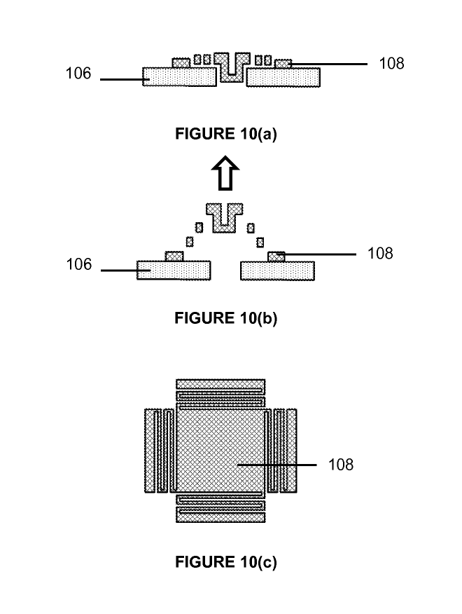

FIGS. 10(a)-(c) show moving the second encapsulation layer 108 away in response to a magnetic or electrostatic force. Referring to FIG. 10(b), the second encapsulation layer 108 moves in the same direction of the applied magnetic or electrostatic force. In other words, the second encapsulation layer 108 moves upward and away from the first encapsulation layer 106. An exemplary second encapsulation layer 108 may move 11 micrometer when exposed to a 200 micro Newton force. The exemplary second encapsulation layer 108 may be made of nickel or other magnetic materials such as iron, cobalt or any combination including nickel, iron and/or cobalt. Further, the exemplary second encapsulation layer maybe 1 um long by 45 um wide by 46 um long. A permanent magnet may generate 200 micro Newton force.

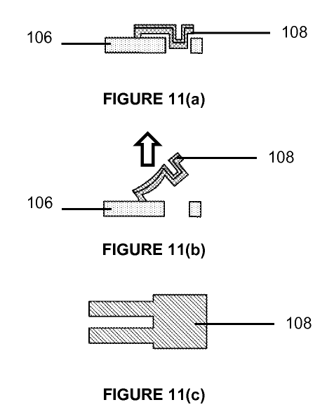

FIGS. 11(a)-(c) show moving the second encapsulation layer 108 away in response to increasing an applied temperature. The second encapsulation layer 108 is made of two materials which have different thermal expansion coefficients. One of these two materials has a lower thermal expansion coefficient. Referring to FIG. 11(a)-(b), the second encapsulation layer 108 will move in a direction that is in line with the direction of movement of the material having a lower thermal expansion coefficient. The other end of the second encapsulation layer 108 moves in the same direction of the applied temperature. In other words, the second encapsulation layer 108 moves upward and away from the first encapsulation layer 106, as shown in FIG. 6(b), while being coupled at one end. The first sacrificial layer 116(a) may etch away through the exposed area.

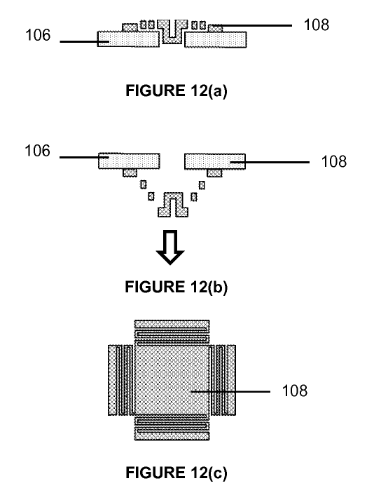

FIGS. 12(a)-(c) show moving the second encapsulation layer 108 away in response to gravitational force. Referring to FIG. 12(a), the second encapsulation layer 108 is provided over the aperture. In the embodiment, the second encapsulation layer 108 may be made of a material with a low spring constant. Referring to FIG. 12(b), the first encapsulation layer 106 and the second encapsulation layer 108 are turned approximately 180 degrees. The second encapsulation layer 108 moves away from the first encapsulation layer 106 in response to the pull of the gravitational force. The low spring constant of the second encapsulation layer 108 may make the second encapsulation layer 108 more responsive to the pull of gravitational force. Referring to FIG. 12(c), part of the meander structure and the covering portion of the second encapsulation layer 108 are moved away from the first encapsulation layer 106.

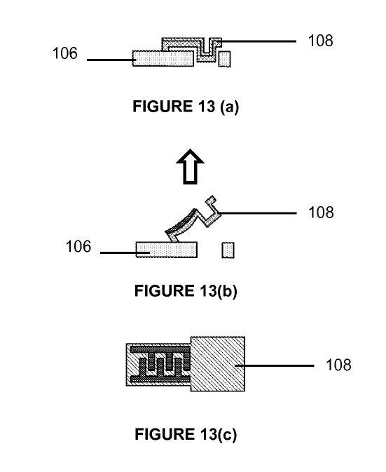

FIGS. 13(a)-(c) show moving the second encapsulation layer 108 away in response to piezoelectric force. The second encapsulation layer 108 may be made of crystalline materials. For example, the piezoelectric materials of the second encapsulation layer 108 result in mechanical force when electrical charges are generated. This in turn moves the second encapsulation layer 108 away from the first encapsulation layer. Advantageously, a thin layer of piezoelectric materials may generate mechanical force to move the second encapsulation layer. As such, the second encapsulation layer may be made of layers in the range of micrometers to generate force necessary to effect translational movement away from the first encapsulation layer.

In other embodiments, external force such as thermal force and electro-thermal force may be used to move the second encapsulation layer 108.

It is to be understood that the illustrations are non-limiting. In an embodiment, an aperture is defined by the first encapsulation layer to allow the etching of the sacrificial layer arrangement. In another embodiment, a plurality of apertures are defined by the first encapsulation layer to allow the etching of the sacrificial layer arrangement. In an embodiment, etching of the sacrificial layer arrangement may be done through one or more of the plurality of apertures.

A discontinuous two encapsulation layers is provided in accordance with embodiments of the invention. Advantageously, mass loading is avoided during encapsulation. The second encapsulation layer lies over and covers portions of the first encapsulation layer. This provides a stable structure formed by the first and second encapsulation layer. It also allows the first and second encapsulation layer to move laterally and/or vertically which reduces the possibility of deformation and stress.

The first encapsulation layer and the second encapsulation layer may be made of the same or different materials. The first and second encapsulation layers may have different expansion coefficients when they are made of different materials. This in turn may cause differential expansion of the first and second encapsulation layers. The overlaying arrangement of the first and second encapsulation layers ensures that the MEMS device remains encapsulated even during expansion of the first and second encapsulation layers at different rates. This in turn better protects the MEMS device.

Additionally, various embodiments of the invention provide that the second encapsulation layer is moved away from the sacrificial layer arrangement. This provides an enclosure around the aperture and the first encapsulation layer. As such the aperture is not subject to receiving any undesirable material during sealing of the encapsulation, thereby effectively prevents mass loading to the MEMS device.

Furthermore, the relatively large etch holes formed by the second encapsulation layer allow the sacrificial layer arrangement to etch away. This provides an effective and fast etching process.

Encapsulation can be a complex technical process. Encapsulation can require quick and accurate fabrication of encapsulation layers over the MEMS device. In some instance, the MEMS device may be damaged during encapsulation since mass loading may happen. Mass loading can cause undesirable materials to be loaded onto the MEMS device during encapsulation. This may cause the MEMS device to malfunction or not function at all. Therefore, reducing mass loading during encapsulation can reduce the probability that the MEMS device to malfunction or break.

It will be appreciated by a person skilled in the art that numerous variations and/or modifications may be made to the present invention as shown in the specific embodiments without departing from the scope of the appended claims as broadly described. The present embodiments are, therefore, to be considered in all respects to be illustrative and not restrictive.

What is claimed is:

1. A method for encapsulating a micro-electromechanical (MEMS) device, the method comprising:
providing a sacrificial layer arrangement over the MEMS device;
providing a first encapsulation layer over the sacrificial layer arrangement, the first encapsulation layer defining at least one aperture;
providing a second encapsulation layer over the at least one aperture, the second encapsulation layer being provided to allow removal of the sacrificial layer arrangement around the second encapsulation layer; and
removing the sacrificial layer arrangement through the at least one aperture to allow the second encapsulation layer to cover the at least one aperture thereby encapsulating the MEMS device.

2. The method according to claim 1, further comprising a step of moving the second encapsulation layer away from the sacrificial layer arrangement to expose the at least one aperture after the step of providing the second encapsulation layer over the sacrificial layer arrangement.

3. The method according to claim 1, further comprising the step of moving the second encapsulation layer towards the first encapsulation layer so as to cover the exposed at least one aperture thereby encapsulating the MEMS device.

4. The method according to claim 2, wherein the steps of moving the second encapsulation layer away from the sacrificial layer arrangement and removing the sacrificial layer arrangement through the exposed aperture are performed at the same time.

5. The method according to claim 1, wherein the sacrificial layer arrangement comprises a first sacrificial layer provided over the MEMS device, the method further comprises providing a second sacrificial layer over the at least one aperture and wherein the removing step comprises removing the first sacrificial layer and the second sacrificial layer.

6. The method according to claim 5, wherein the second sacrificial layer is removed first followed by removing the first sacrificial layer.

7. The method according to claim 5, wherein the first sacrificial layer is removed through the exposed at least one aperture.

8. The method according to claim 1, wherein the second encapsulation layer is moved by an external force.

9. The method according to claim 8, wherein the external force comprises magnetic force, piezoelectric force, gravitational force, thermal force, electro thermal force and electromagnetic force.

10. The method according to claim 8, wherein the second encapsulation layer moves towards the first encapsulation layer when the external force is removed.

11. The method according to claim 5, wherein the sacrificial layer arrangement further comprises a third sacrificial layer, the third sacrificial layer being provided beside the second sacrificial layer.

12. The method according to claim 11, wherein the third sacrificial layer is made of the same material as the first sacrificial layer.

13. The method according to claim 11, wherein the first sacrificial layer and the third sacrificial layer are removed first followed by removing the second sacrificial layer.

14. The method according to claim 1, further comprising patterning the second encapsulation layer.

15. The method according to claim 14, wherein patterning the second encapsulation layer comprises forming a plurality of etch holes, the plurality of etch holes being configured to align with a portion of the first encapsulation layer.

16. The method according to claim 15, wherein a dissolving agent is provided to the sacrificial layer arrangement through the plurality of etch holes.

17. The method according to claim 5, wherein the first sacrificial layer comprises silicon oxide.

18. The method according to claim 5, wherein the second sacrificial layer comprises amorphous silicon, poly silicon and single crystalline silicon.

19. The method according claim 1, wherein the second encapsulation layer comprises a biasing element, the biasing element being coupled to the first encapsulation layer so as to allow the second encapsulation layer to move away from the sacrificial layer arrangement.

20. The method according to claim 1, wherein encapsulating the MEMS device comprises enclosing the MEMS device under vacuum.

21. The method according to claim 1, wherein the second encapsulation layer comprises nickel, iron, cobalt or any combination including nickel, iron and/or cobalt.

22. The method according to claim 1, further comprising forming a sealing layer to enclose the first and second encapsulation layers.

23. The method according to claim 1, wherein the aperture is arranged in a substantially central location on an upper surface of the sacrificial layer arrangement.

24. The method according to claim 6, wherein the first and second sacrificial layers are made of different materials.

25. The method according to claim 1, wherein the first and second encapsulation layers are made of different materials.

26. The method according to claim 22, wherein the first encapsulation layer and the second encapsulation layer are configured to release stress during the step of forming a sealing layer.

27. The method according to claim 22, wherein the first encapsulation layer and the second encapsulation layer are configured to release stress after the step of forming a sealing layer.
